(19) United States
(12) Patent Application Publication
(10) Pub. No.: US 2023/0411846 A1
(43) Pub. Date: Dec. 21, 2023

(54) DECOUPLING CIRCUIT

(71) Applicant: Mitsubishi Electric Corporation, Tokyo (JP)

(72) Inventors: Kengo NISHIMOTO, Tokyo (JP); Yasuhiro NISHIOKA, Tokyo (JP)

(73) Assignee: Mitsubishi Electric Corporation, Tokyo (JP)

(21) Appl. No.: 18/240,066

(22) Filed: Aug. 30, 2023

Related U.S. Application Data
(63) Continuation of application No. PCT/JP2021/012492, filed on Mar. 25, 2021.

(51) Int. Cl. H01Q 5/335; H01Q 5/371; H01Q 5/50

(52) U.S. Cl. CPC H01Q 5/335; H01Q 5/371; H01Q 5/50

(57) ABSTRACT

A decoupling circuit includes: a first transmission line whose first end is connected to the first antenna element; a second transmission line whose first end is connected to the second antenna element; a first susceptance circuit whose first end is connected to a second end of the first transmission line; a second susceptance circuit whose first end is connected to a second end of the second transmission line and whose second end is connected to a second end of the first susceptance circuit; a third susceptance circuit whose first end is connected to the second end of the first susceptance circuit and whose second end is connected to the ground conductor; a first input and output terminal connected to the first end of the first susceptance circuit; and a second input and output terminal connected to the first end of the second susceptance circuit.

### CROSS REFERENCE TO RELATED APPLICATIONS

This application is a Continuation of PCT International Application No. PCT/JP2021/012492 filed on Mar. 25, 2021, which is hereby expressly incorporated by reference into the present application.

### TECHNICAL FIELD

The present invention relates to a decoupling circuit connected to a plurality of antennas mounted on a wireless communication device or the like.

### BACKGROUND ART

In recent years, with an increase in speed and quality of a wireless communication system, there is an increasing demand for multi-antenna technology using a plurality of antennas for transmission and reception in order to apply diversity and multiple input multiple output (MIMO).

In addition, there is an increasing need to operate a wireless communication device in a plurality of frequency bands in order to increase the speed and quality and to mount a plurality of wireless communication systems. In order for diversity and MIMO to be effective, it is necessary to reduce coupling between a plurality of antennas as much as possible and to reduce antenna correlation.

However, in a case where a communication device is small, a region for mounting a plurality of antennas is limited, and a distance between the antennas cannot be sufficiently ensured. For this reason, coupling between the antennas is strong, and communication performance is deteriorated. For this problem, there is a method for reducing coupling between the antennas by connecting a decoupling circuit to the antennas.

Patent Literature 1 discloses an example in which a decoupling circuit that reduces mutual coupling in a two-element antenna and corresponds to one frequency is constituted by three susceptances.

### CITATION LIST

### Patent Literature

Patent Literature 1: JP 5871647 B2

### SUMMARY OF INVENTION

### Technical Problem

However, in the decoupling circuit corresponding to one frequency of Patent Literature 1, two matching circuits are required on a side opposite to the two-element antenna as viewed from the decoupling circuit. In order to match any impedance at one frequency, the matching circuit needs to be a IT type circuit or a T type circuit including three susceptances. There are two matching circuits, there are three susceptances in the decoupling circuit, and therefore nine susceptances are required in total. Therefore, there is a problem that the number of susceptances increases and a circuit loss increases.

The present invention has been made in order to solve the above problem, and an object of the present invention is to obtain a decoupling circuit corresponding to one frequency or two frequencies, the decoupling circuit having a small number of susceptances, being capable of reducing a circuit loss, and having a small restriction on an impedance matrix of a two-element antenna.

### Solution to Problem

A decoupling circuit of the present invention includes: a first antenna element; a second antenna element; a ground conductor; a first transmission line whose first end is connected to the first antenna element; a second transmission line whose first end is connected to the second antenna element; a first susceptance circuit whose first end is connected to a second end of the first transmission line; a second susceptance circuit whose first end is connected to a second end of the second transmission line and whose second end is connected to a second end of the first susceptance circuit; a third susceptance circuit whose first end is connected to the second end of the first susceptance circuit and whose second end is connected to the ground conductor; a first input and output terminal connected to the first end of the first susceptance circuit; and a second input and output terminal connected to the first end of the second susceptance circuit, wherein the first susceptance circuit is a first parallel resonance circuit, the second susceptance circuit is a second parallel resonance circuit.

### Advantageous Effects of Invention

According to the present invention, it is possible to implement a decoupling circuit corresponding to one frequency or two frequencies, the decoupling circuit having a small number of susceptances, being capable of reducing a circuit loss, and having a small restriction on an impedance matrix of a two-element antenna.

### BRIEF DESCRIPTION OF DRAWINGS

FIG. 1 is a diagram illustrating a decoupling circuit according to a first embodiment.

FIG. 2 is a diagram illustrating a configuration of a two-element antenna that has been subjected to electromagnetic field simulation.

FIG. 3A and FIG. 3B illustrate calculation results of an S parameter in a case where a decoupling circuit is applied and in a case where the decoupling circuit is not applied.

FIG. 4 is a diagram illustrating a decoupling circuit according to a second embodiment.

FIG. 5A and FIG. 5B are diagrams illustrating a phase shift circuit at one frequency.

FIG. 6A and FIG. 6B are diagrams illustrating a configuration of a two-frequency shared phase shift circuit.

FIG. 7A and FIG. 7B are diagrams illustrating configurations of resonance circuits 71 to 79.

FIG. 8 is a diagram illustrating a decoupling circuit according to a third embodiment.

FIG. 9 is an equivalent circuit of the decoupling circuit according to the third embodiment at f2.

FIG. 10 is a diagram illustrating a case where a series resonance circuit and a ground conductor are replaced with transmission lines in the decoupling circuit according to the third embodiment.

FIG. 11 is a diagram illustrating a decoupling circuit according to a fourth embodiment.

### DESCRIPTION OF EMBODIMENTS

### First Embodiment

FIG. 1 is a diagram illustrating a decoupling circuit according to the present embodiment.

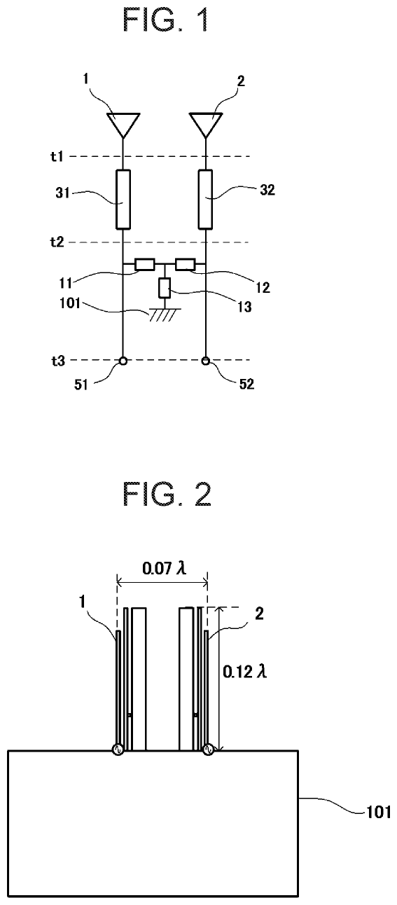

FIG. 2 is a diagram illustrating a configuration of a two-element antenna that has been subjected to electromagnetic field simulation in order to confirm an effect of the decoupling circuit according to the present embodiment.

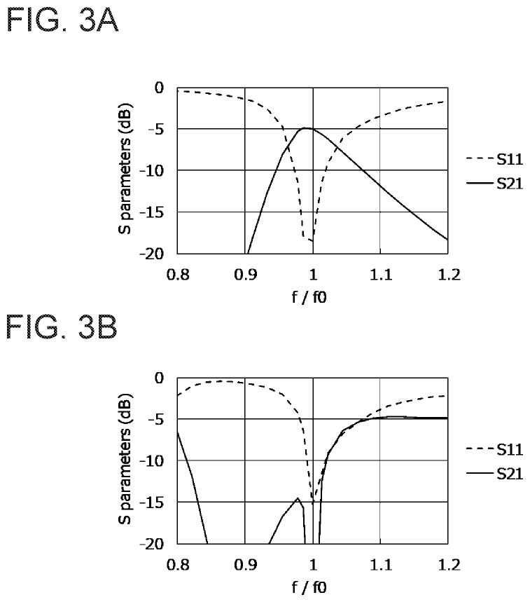

FIG. 3 illustrates calculation results of an S parameter in a case where the decoupling circuit according to the first embodiment is applied to the two-element antenna in FIG. 2 and in a case where the decoupling circuit is not applied.

In FIG. 1, the decoupling circuit according to the present embodiment includes antenna elements 1 and 2, susceptances (susceptance circuits) 11 to 13, a ground conductor 101, transmission lines 31 and 32, and input and output terminals 51 and 52.

The susceptance circuits 11 to 13 may be each constituted by a susceptance element or a resonance circuit. In addition, the susceptance circuits 11 to 13 may be each constituted by a plurality of susceptance elements. In the present embodiment, a case where the susceptances 11 to 13 are each constituted by a susceptance element will be described.

One end (first end) of the transmission line 31 is connected to the antenna element 1, and the other end (second end) thereof is connected to one end (first end) of the susceptance 11.

One end (first end) of the transmission line 32 is connected to the antenna element 2, and the other end (second end) thereof is connected to one end (first end) of the susceptance 12.

The other end (second end) of the susceptance 11 is connected to the other end (second end) of the susceptance 12.

One end (first end) of the susceptance 13 is connected to the other end (second end) of the susceptance 11, and the other end (second end) thereof is connected to the ground conductor 101.

The input and output terminal 51 is connected to the one end (first end) of the susceptance 11, and the input and output terminal 52 is connected to the one end (first end) of the susceptance 12.

Note that reference planes t1 to t3 each represent a plane on which an S parameter of two ports on an antenna side is observed.

Next, operation of the present decoupling circuit will be described.

A reference impedance when the antenna elements 1 and 2 are viewed from the reference planes t1 and t2 in FIG. 1 is represented by Z₁, and a reference impedance of the input and output terminals 51 and 52 is represented by Z₀. Note that Z₀ is usually 50Ω.

An amplitude of mutual coupling between the antenna elements 1 and 2 when the antenna elements 1 and 2 are viewed from the reference plane t1 is represented by α Z₁ is represented by the following formula:

$${Z}_{1} = \frac{1 - {α}^{2}}{1 + {α}^{2}} {Z}_{0} \qquad ( 1 )$$

and the shapes of the antenna elements 1 and 2 are adjusted in such a manner that reflection of the antenna elements 1 and 2 on the reference plane t1 is reduced.

In a case where the ground conductor 101, a metal, a dielectric, or the like is present in the vicinity of the antenna elements 1 and 2, the shapes thereof and arrangement thereof are also adjusted. Note that matching circuits may be arranged between the antenna element 1 and the transmission line 31 and between the antenna element 2 and the transmission line 32, respectively.

A characteristic impedance of each of the transmission lines 31 and 32 is represented by Z₁. In addition, the length of the transmission line 31 is represented by L₁, and the length of the transmission line 32 is represented by L₂.

The lengths L₁ and L₂ are determined in such a manner that a phase of mutual coupling between the antenna elements 1 and 2 when the antenna elements 1 and 2 are viewed from the reference plane t2 is +90 degrees.

A reference impedance is represented by Z₀, and an S parameter of the two ports when the antenna elements 1 and 2 are viewed from the reference plane t3 is represented by S_{c}. If a value B₁ of each of the susceptances 11 and 12 is represented by the following formula

$${B}_{1} = \frac{∓ 2 α}{{Z}_{1} ( 1 + {α}^{2} )} \qquad ( 2 )$$

and a value B₂ of the susceptance 13 is represented by the following formula,

B₂=−B₁ (3)

that is, if B₂ is an opposite number of B₁, reflections |S_{C11}| and |S_{C22}| and mutual coupling |S_{C21}| when the antenna elements 1 and 2 are viewed from the reference plane t3 can be reduced.

As described above, in the decoupling circuit according to the first embodiment of the present invention, it is possible to reduce both mutual coupling and reflection at one frequency only with the three susceptances. In addition, since a restriction condition on the antenna elements 1 and 2 is only to reduce reflection of the antenna elements 1 and 2 with the reference impedance of formula (1), the decoupling circuit can also be applied to an asymmetric two-element antenna, and the restriction on the two-element antenna configuration can be reduced. That is, restriction on an impedance matrix (S parameter) of the two-element antenna can be reduced.

Results of performing electromagnetic field simulation for the two-element antenna illustrated in FIG. 2 in order to confirm an effect of the decoupling circuit according to the first embodiment will be described.

In FIG. 2, λ represents a free space wavelength at a design frequency f. The antenna elements 1 and 2 are monopole antennas formed on a dielectric substrate 61 (relative dielectric constant 7, dielectric loss tangent 0.01, thickness 0.01λ0), and are arranged close to an upper side of the planar ground conductor 101.

Here, when Z₀=50Ω is satisfied, the dimensions of the two-element antenna are adjusted in such a manner that the amplitude a of the mutual coupling between the antenna elements 1 and 2 is −5 dB and Z₁ is 25Ω from formula (1).

FIG. 3A illustrates calculation results of an S parameter of the model of FIG. 2 when Z₁=25Ω is satisfied for a reference impedance. Note that, since the model of FIG. 2 is plane-symmetric, only reflection S₁₁ of the antenna element 1 and mutual coupling S₂₁ between the antenna elements 1 and 2 are illustrated, and reflection S₂₂ of the antenna element 2 is omitted. S₂₂ is equal to S₁₁.

From FIG. 3A, it can be confirmed that, at f0, the reflection S₁₁ is reduced to −18.5 dB, but the mutual coupling S₂₁ is as high as −5.0 dB.

Next, in the decoupling circuit of FIG. 1, the length L₁ of the transmission line 31 and the length L₂ of the transmission line 32 are adjusted in such a manner that a phase of mutual coupling between the antenna elements 1 and 2 when the antenna elements 1 and 2 are viewed from the reference plane t2 is ±90 degrees, and L₁=L₂=20 degrees is satisfied for an electrical length f. Note that Z₁=25Ω is satisfied fora characteristic impedance of each of the transmission lines 31 and 32. Then, a value B₁ of each of the susceptances 11 and 12 and a value B₂ of the susceptance 13 are obtained from formulas (2) and (3).

FIG. 3B illustrates calculation results of an S parameter in a case where the decoupling circuit of FIG. 1 determined as described above is applied to the two-element antenna of FIG. 2.

In the S parameter of FIG. 3B, Z₀=50Ω is satisfied for a reference impedance. From FIG. 3B, at f0, the reflection S₁₁ is −15.2 dB, the mutual coupling S₂₁ is −38.0 dB, and it can be confirmed that both the reflection and the mutual coupling are reduced.

Note that FIG. 2 illustrates a configuration example of a two-element antenna, and the decoupling circuit of the present first embodiment can be applied to a two-element antenna having any shape as long as reflection of the antenna elements 1 and 2 can be reduced with the reference impedance of formula (1).

As described above, by the decoupling circuit being constituted by the antenna elements 1 and 2, the susceptance 11 to 13, the ground conductor 101, the transmission lines 31 and 32, and the input and output terminals 51 and 52, it is possible to obtain a decoupling circuit having a small number of susceptances, having a small restriction on an impedance matrix of a two-element antenna, and being capable of reducing both mutual coupling and reflection at one frequency.

### Second Embodiment

In the present embodiment, a case where the decoupling circuit according to the first embodiment is extended to two frequencies will be described.

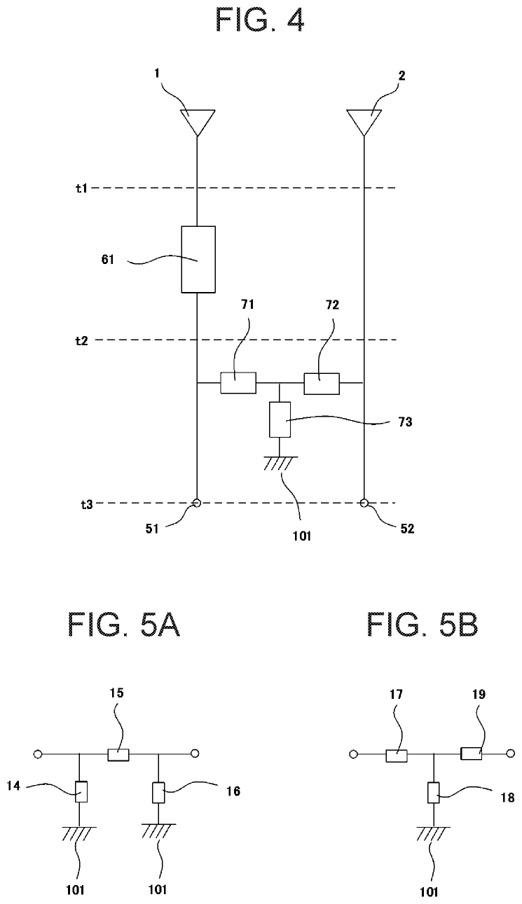

FIG. 4 is a diagram illustrating a decoupling circuit according to the present embodiment. Note that the same reference numerals as in FIG. 1 indicate the same or corresponding parts.

In FIG. 4, the decoupling circuit according to the present embodiment includes antenna elements 1 and 2, a two-frequency shared phase shift circuit 61, resonance circuits 71 to 73, aground conductor 101, and input and output terminals 51 and 52.

In the present embodiment, a case where susceptances 11 to 13 are constituted by the resonance circuits 71 to 73, respectively is described.

Note that the two-frequency shared phase shift circuit 61 is disposed in place of the transmission lines 31 and 32 in the decoupling circuit of FIG. 1.

One end (first end) of the two-frequency shared phase shift circuit 61 is connected to the antenna element 1.

One end (first end) of the resonance circuit 72 is connected to the antenna element 2.

One end (first end) of the resonance circuit 71 is connected to the other end (second end) of the two-frequency shared phase shift circuit 61, and the other end (second end) thereof is connected to the other end (second end) of the resonance circuit 72.

One end (first end) of the resonance circuit 73 is connected to the other end (second end) of the resonance circuit 71, and the other end (second end) thereof is connected to the ground conductor 101.

The input and output terminal 51 is connected to the one end (first end) of the resonance circuit 71, and the input and output terminal 52 is connected to the one end (first end) of the resonance circuit 72.

The two-frequency shared phase shift circuit 61 is a circuit that changes a pass phase at two frequencies.

FIG. 5 illustrates a phase shift circuit at one frequency.

FIG. 5A illustrates a phase shift circuit constituted by a Π type circuit including three susceptances 14, 15, and 16.

FIG. 5B illustrates a phase shift circuit constituted by a T type circuit including three susceptances 17, 18, and 19.

In both the phase shift circuits of FIGS. 5A and 5B, it is possible to delay or advance a pass phase by adjusting a value of a susceptance used.

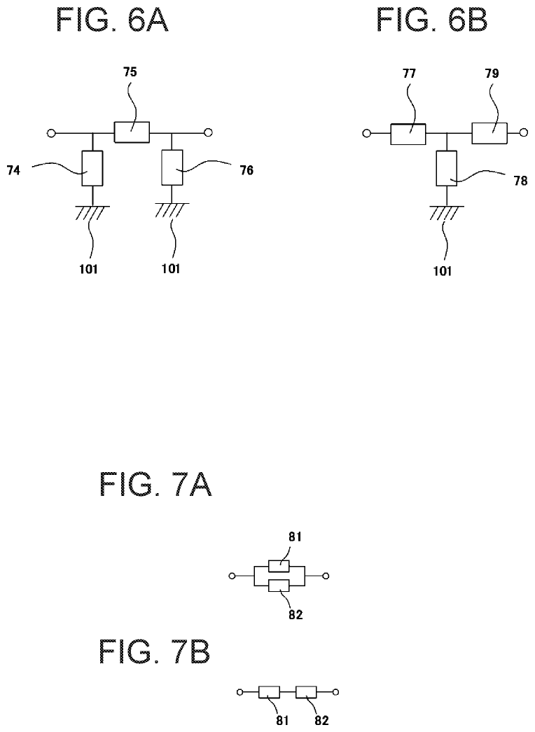

FIG. 6 illustrates a configuration of the two-frequency shared phase shift circuit 61.

FIG. 6A is obtained by replacing susceptances 14, 15, and 16 in FIG. 5A with resonance circuits 74, 75, and 76, respectively.

FIG. 6B is obtained by replacing susceptances 17, 18, and 19 in FIG. 5B with resonance circuits 77, 78, and 79, respectively.

By replacing the susceptance with the resonance circuit in this manner, a pass phase can be delayed or advanced at two frequencies. In addition, pass phases different between two frequencies can be achieved.

FIG. 7 illustrates configurations of the resonance circuits 71 to 79.

FIG. 7A illustrates an example of a series resonance circuit of an inductor 81 and a capacitor 82.

FIG. 7B illustrates an example of a parallel resonance circuit of the inductor 81 and the capacitor 82.

Therefore, susceptances different between two frequencies can be achieved.

Note that since an inductance value of a commercially available inductor is discrete, an inductance of the inductor 81 may be achieved by a plurality of inductors and capacitors. Similarly, since a capacitance value of a commercially available capacitor is discrete, a capacitance of the capacitor 82 may be achieved by a plurality of inductors and capacitors.

Next, operation of the present decoupling circuit will be described. In the present embodiment, frequencies at which reflection of the antenna elements 1 and 2 and mutual coupling between the antenna elements 1 and 2 are reduced are represented by f1 (first frequency) and f2 (second frequency). In addition, f2 is a frequency higher than f1.

Reference impedances when the antenna elements 1 and 2 are viewed from reference planes t1 and t2 in FIG. 4 are represented by Z₁ₗ and Z₁ₕ at f1 and f2, respectively. A reference impedance of the input and output terminals 51 and 52 at f1 and f2 is represented by Z₀. Z₀ is usually 50Ω.

Amplitudes of mutual coupling between the antenna elements 1 and 2 when the antenna elements 1 and 2 are viewed from the reference plane t1 at f1 and 12 are represented by αₗ and αₕ, respectively Z₁ₗ and Z₁ₕ are represented by the following formulas:

$${Z}_{1 l} = \frac{1 - {α}_{l}^{2}}{1 + {α}_{l}^{2}} {Z}_{0} \qquad ( 4 )$$

$$and$$

$${Z}_{1 h} = \frac{1 - {α}_{h}^{2}}{1 + {α}_{h}^{2}} {Z}_{0} \qquad ( 5 )$$

and the shapes of the antenna elements 1 and 2 are adjusted in such a manner that reflection of the antenna elements 1 and 2 on the reference plane t1 is reduced at f1 and f2.

In a case where the ground conductor 101, a metal, or a dielectric is present in the vicinity of the antenna elements 1 and 2, the shapes thereof and arrangement thereof are also adjusted. Note that matching circuits may be arranged between the antenna elements 1 and the two-frequency shared phase shift circuit 61 and between the antenna element 2 and the resonance circuit 72, respectively.

In a case where reference impedances at f1 and f2 are Z₁ₗ and Z₁ₕ, respectively, a pass phase of the two-frequency shared phase shift circuit 61 is adjusted in such a manner that a phase of mutual coupling between the antenna elements 1 and 2 when the antenna elements 1 and 2 are viewed from the reference plane t2 is ±90 degrees at f1 and f2.

A reference impedance is represented by Z₀, and an S parameter of the two ports when the antenna elements 1 and 2 are viewed from the reference plane 3 is represented by S_{c}.

Susceptances of the resonance circuit 71 at f1 and 12 are represented by B₁ₗ and B₁ₕ, respectively.

Susceptances of the resonance circuit 72 at f1 and f2 are represented by B₁ₗ and B₁ₕ, respectively.

In addition, susceptances of the resonance circuit 73 at f1 and 12 are represented by B₂ₗ and B₂ₕ, respectively.

If B₁ₗ, B₁ₕ, B₂ₗ, and B₂ₕ are represented by the following formulas,

$${B}_{1 l} = \frac{∓ 2 {α}_{l}}{{Z}_{1 l} ( 1 + {α}_{l}^{2} )} \qquad ( 6 )$$

$${B}_{1 h} = \frac{∓ 2 {α}_{h}}{{Z}_{1 h} ( 1 + {α}_{h}^{2} )} \qquad ( 7 )$$

$${B}_{2 l} = - {B}_{1 l} \qquad ( 8 )$$

$${B}_{2 h} = - {B}_{1 h} \qquad ( 9 )$$

reflections |S_{C11}| and |S_{C22}| and mutual coupling |S_{C21}| when the antenna elements 1 and 2 are viewed from the reference plane 3 can be reduced at f1 and f2.

As described above, in the decoupling circuit according to the present embodiment, since a restriction condition on the antenna elements 1 and 2 is only to reduce reflection of the antenna elements 1 and 2 with the reference impedances of formulas (4) and (5), the decoupling circuit according to the present embodiment can also be applied to an asymmetric two-element antenna, and the restriction on the two-element antenna configuration can be reduced.

As described above, by the decoupling circuit being constituted by the antenna elements 1 and 2, the two-frequency shared phase shift circuit 61, the resonance circuits 71 to 73, the ground conductor 101, and the input and output terminals 51 and 52, it is possible to obtain a decoupling circuit having a small restriction on an impedance matrix of a two-element antenna, and being capable of reducing both mutual coupling and reflection at two frequencies.

### Third Embodiment

In the present embodiment, a case where the decoupling circuit according to the first embodiment is extended to two frequencies and a configuration thereof is further simplified will be described.

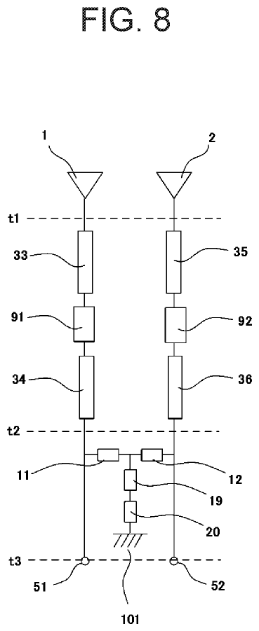

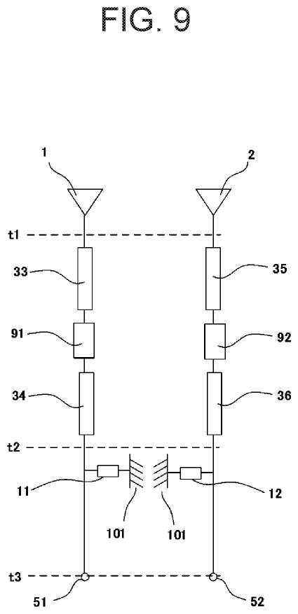

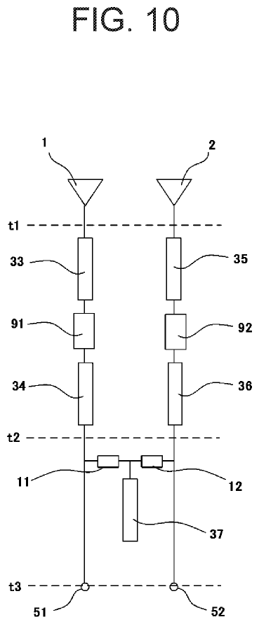

FIG. 8 is a diagram illustrating a decoupling circuit according to the present embodiment.

In FIG. 8, the decoupling circuit according to the present embodiment newly includes a matching circuit 91, a matching circuit 92, a susceptance 19, and a susceptance 20.

The matching circuit 91 is disposed in the middle of a transmission line 31, and the matching circuit 92 is disposed in the middle of a transmission line 32. In addition, the susceptances 19 and 20 form a series resonance circuit disposed in place of a susceptance 13.

FIG. 9 is an equivalent circuit of the decoupling circuit of FIG. 8 at f2.

FIG. 10 is a diagram obtained by replacing the series resonance circuit constituted by the susceptances 19 and 20 and a ground conductor 101 with a transmission line 37 in the decoupling circuit of FIG. 8.

In the decoupling circuit of FIG. 8, the transmission line 31 in the decoupling circuit of FIG. 1 is divided into transmission lines 33 and 34, and the matching circuit 91 is disposed between the transmission lines 33 and 34.

Similarly, the transmission line 32 is divided into transmission lines 35 and 36, and the matching circuit 92 is disposed between the transmission lines 35 and 36.

Furthermore, the susceptance 13 is replaced with the series resonance circuit constituted by the susceptances 19 and 20.

Next, operation of the present decoupling circuit will be described.

In the present embodiment, frequencies at which reflection of antenna elements 1 and 2 and mutual coupling between the antenna elements 1 and 2 are reduced are represented by f1 (first frequency) and f2 (second frequency). In addition, f2 is a frequency higher than f1.

A reference impedance when the antenna elements 1 and 2 are viewed from reference planes t1 and t2 in FIG. 8 is represented by Z₁. A reference impedance of input and output terminals 51 and 52 is represented by Z₀. Z₀ is usually 50Ω.

An amplitude of mutual coupling between the antenna elements 1 and 2 when the antenna elements 1 and 2 are viewed from the reference plane t1 is represented by au at f1. The reference impedance Z₁ is represented by the following formula:

$${Z}_{1} = \frac{1 - {α}_{l}^{2}}{2 + {α}_{l}^{2}} {Z}_{0} \qquad ( 10 )$$

and the shapes of the antenna elements 1 and 2 are adjusted in such a manner that reflection of the antenna elements 1 and 2 on the reference planet 1 is reduced at f1 and mutual coupling between the antenna elements 1 and 2 on the reference planet 1 is reduced at f2.

In a case where the ground conductor 101, a metal, or a dielectric is present in the vicinity of the antenna elements 1 and 2, the shapes thereof and arrangement thereof are also adjusted.

A characteristic impedance of each of the transmission lines 31 and 32 is represented by Z₁. In addition, the length of the transmission line 31 is represented by L₁, and the length of the transmission line 32 is represented by L₂.

The lengths L₁ and L₂ are determined in such a manner that a phase of mutual coupling between the antenna elements 1 and 2 when the antenna elements 1 and 2 are viewed from the reference plane t2 is 90 degrees at f1.

A reference impedance is represented by Z₀, and an S parameter of the two ports when the antenna elements 1 and 2 are viewed from a reference plane t3 is represented by S_{c}. A value B₁ of each of the susceptances 11 and 12 is represented by the following formula.

$${B}_{1} = \frac{- 2 {α}_{l}}{{Z}_{1} ( 1 + {α}_{l}^{2} )} \qquad ( 11 )$$

In addition, the series resonance circuit constituted by the susceptances 19 and 20 is determined in such a manner that a susceptance satisfies the following formula at f1:

B₂=−B₁ (12)

and the series resonance circuit is short-circuited (susceptance is infinite) at f2. That is, the susceptance 19 satisfies, as an inductor L, the following formula.

$$L = \frac{1}{2 π {f}_{2} {B}_{1} ( {f}_{1} / {f}_{2} - {f}_{2} / {f}_{1} )} \qquad ( 13 )$$

and the susceptance 20 satisfies, as a capacitor C, the following formula.

$$C = \frac{{B}_{1} ( {f}_{1} / {f}_{2} - {f}_{2} / {f}_{1} )}{2 π {f}_{2}} \qquad ( 14 )$$

In this way, reflections |S_{C11}| and |S_{C22}| and mutual coupling |S_{C11}| when the antenna elements 1 and 2 are viewed from the reference plane t3 can be reduced at f1. In addition, since the series resonance circuit constituted by the susceptances 19 and 20 is short-circuited at f2, the decoupling circuit of FIG. 8 can be considered as in FIG. 9 at f2.

That is, it can be considered that the susceptances 19 and 20 are removed, the ground conductor 101 is connected to the other end (second end) of the susceptance 11, and the ground conductor 101 is connected to the other end (second end) of the susceptance 12.

At f2, since the circuit on the antenna element 1 side and the circuit on the antenna element 2 side are not connected to each other, the circuits of FIG. 9 do not affect mutual coupling, and the mutual coupling remains reduced at f2.

Note that the susceptances 19 and 20 and the ground conductor 101 in FIG. 8 may be replaced with the transmission line 37 as illustrated in FIG. 10. One end (first end) of the transmission line 37 is connected to the other end (second end) of the susceptance 11, and the other end (second end) thereof is open.

If an electrical length of the transmission line 37 is about 0.25 wavelengths at f2, it can be considered that one end (first end) of the transmission line 37 is connected to the ground conductor 101 at f2. In addition, a characteristic impedance of the transmission line 37 is determined in such a manner that a susceptance when the transmission line 37 is viewed from the one end (first end) of the transmission line 37 satisfies formula (12) at f1.

In this way, the decoupling circuit of FIG. 10 can implement the same operation as the decoupling circuit of FIG. 8.

Furthermore, by disposing the matching circuit 91 in the middle of the transmission line 31 and disposing the matching circuit 92 in the middle of the transmission line 32, a reflection amplitude is reduced at f2.

A configuration of each of the matching circuits 91 and 92 is not specified in the present third embodiment, but for example, a series resonance circuit of an inductor and a capacitor arranged in series in each of the transmission lines 31 and 32 is conceivable. In addition, a parallel resonance circuit of an inductor and a capacitor arranged in parallel in each of the transmission lines 31 and 32 is conceivable.

In the former case, the series resonance circuit is short-circuited at f1 so as not to affect characteristics of f1.

In the latter case, the parallel resonance circuit is open at f1 so as not to affect characteristics of f1. The number of the matching circuits 91 is not limited to one, and a plurality of the matching circuits 91 may be arranged in the middle of the transmission line 31. Similarly, the number of the matching circuits 92 is not limited to one, and a plurality of the matching circuits 92 may be arranged in the middle of the transmission line 32.

As described above, in the decoupling circuit according to the third embodiment of the present invention, since a restriction condition on the antenna elements 1 and 2 is to reduce reflection of the antenna elements 1 and 2 with the reference impedance of formula (10) at f1, and to reduce mutual coupling at f2, the decoupling circuit can also be applied to an asymmetric two-element antenna, and the restriction on the two-element antenna configuration can be reduced.

As described above, by the decoupling circuit being constituted by the antenna elements 1 and 2, the susceptances 11, 12, 19, and 20, the ground conductor 101, the transmission lines 33, 34, 35, 36, and 37, the matching circuits 91 and 92, and the input and output terminals 51 and 52, it is possible to obtain a decoupling circuit having a small number of susceptances, having a small restriction on an impedance matrix of a two-element antenna, and being capable of reducing both mutual coupling and reflection at two frequencies.

### Fourth Embodiment

In the present embodiment, a case where the decoupling circuit according to the first embodiment is extended to two frequencies and a configuration thereof is simplified will be described.

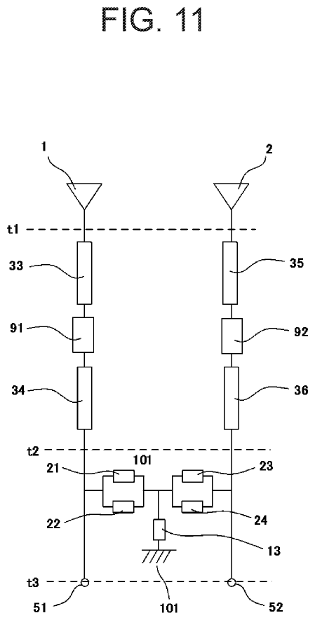

FIG. 11 is a diagram illustrating a decoupling circuit according to the present embodiment. Note that the same reference numerals as in FIG. 1 indicate the same or corresponding parts.

In FIG. 11, the decoupling circuit according to the present embodiment newly includes a matching circuit 91, a matching circuit 92, a susceptance 21, a susceptance 22, a susceptance 23, and a susceptance 24.

Note that the matching circuit 91 is disposed in the middle of the transmission line 31 in FIG. 1, and the matching circuit 92 is disposed in the middle of the transmission line 32. The susceptances 21 and 22 form a parallel resonance circuit (first parallel resonance circuit) disposed in place of the susceptance 11 in FIG. 1, and the susceptances 23 and 24 form a parallel resonance circuit (second parallel resonance circuit) disposed in place of the susceptance 12 in FIG. 1.

In the decoupling circuit of FIG. 11, the transmission line 31 in the decoupling circuit of FIG. 1 is divided into transmission lines 33 and 34, and the matching circuit 91 is disposed between the transmission lines 33 and 34. In addition, the transmission line 32 is divided into transmission lines 35 and 36, and the matching circuit 92 is disposed between the transmission lines 35 and 36. Furthermore, the susceptance 11 is replaced with the first parallel resonance circuit constituted by the susceptances 21 and 22, and the susceptance 12 is replaced with the second parallel resonance circuit constituted by the susceptances 23 and 24.

Next, operation of the present decoupling circuit will be described.

In the present embodiment, frequencies at which reflection of antenna elements 1 and 2 and mutual coupling between the antenna elements 1 and 2 are reduced are represented by f1 (first frequency) and f2 (second frequency). In addition, f2 is a frequency higher than f1.

A reference impedance when the antenna elements 1 and 2 are viewed from reference planes t1 and t2 in FIG. 8 is represented by Z₁.

A reference impedance of input and output terminals 51 and 52 is represented by Z₀. Note that Z₀ is usually 50Ω.

An amplitude of mutual coupling between the antenna elements 1 and 2 when the antenna elements 1 and 2 are viewed from the reference plane t1 is represented by αₗ at f1.

The reference impedance Z₁ is represented by the following formula:

$${Z}_{1} = \frac{1 - {α}_{i}^{2}}{1 + {α}_{l}^{2}} {Z}_{0} \qquad ( 15 )$$

and the shapes of the antenna elements 1 and 2 are adjusted in such a manner that reflection of the antenna elements 1 and 2 on the reference plane t1 is reduced at f1 and mutual coupling between the antenna elements 1 and 2 on the reference plane t1 is reduced at f2. In a case where the ground conductor 101, a metal, or a dielectric is present in the vicinity of the antenna elements 1 and 2, the shapes thereof and arrangement thereof are also adjusted.

A characteristic impedance of each of the transmission lines 31 and 32 is represented by Z₁. In addition, the length of the transmission line 31 is represented by L₁, and the length of the transmission line 32 is represented by L₂.

The lengths L₁ and L₂ are determined in such a manner that a phase of mutual coupling between the antenna elements 1 and 2 when the antenna elements 1 and 2 are viewed from the reference plane t2 is 90 degrees at f1.

A reference impedance is represented by Z₀, and an S parameter of the two ports when the antenna elements 1 and 2 are viewed from a reference plane t3 is represented by S_{c}. Here, B₁ is represented by the following formula.

$${B}_{1} = \frac{- 2 {α}_{l}}{{Z}_{1} ( 1 + {α}_{l}^{2} )} \qquad ( 16 )$$

The first parallel resonance circuit constituted by the susceptances 21 and 22 is determined in such a manner that a susceptance satisfies formula (16) at f1, and the first parallel resonance circuit is open at 2.

Similarly, the second parallel resonance circuit constituted by the susceptances 23 and 24 is also determined in such a manner that a susceptance satisfies formula (16) at f1, and the second parallel resonance circuit is open at f2.

That is, the susceptances 21 and 23 satisfy, as an inductor L, the following formula,

$$L = \frac{( {f}_{1} / {f}_{2} - {f}_{2} / {f}_{1} )}{2 π {f}_{2} {B}_{1}} \qquad ( 17 )$$

and the susceptances 22 and 24 satisfy, as a capacitor C, the following formula.

$$C = \frac{{B}_{1}}{2 π {f}_{2} ( {f}_{1} / {f}_{2} - {f}_{2} / {f}_{1} )} \qquad ( 18 )$$

In addition, a value B₂ of the susceptance 13 is represented by the following formula.

B₂=−B₁ (19)

In this way, reflections |S_{C11}| and |S_{C22}| and mutual coupling |S_{C21}| when the antenna elements 1 and 2 are viewed from the reference plane t3 can be reduced at f1. In addition, the first parallel resonance circuit constituted by the susceptances 21 and 22 and the second parallel resonance circuit constituted by the susceptances 23 and 24 are open at f2. Therefore, the decoupling circuit of FIG. 11 is equivalent to a circuit without the susceptances 13 and 21 to 24 in FIG. 11 at f2, and therefore the mutual coupling remains reduced at f2.

Furthermore, by disposing the matching circuit 91 in the middle of the transmission line 31 and disposing the matching circuit 92 in the middle of the transmission line 32, a reflection amplitude is reduced at f2. A configuration of each of the matching circuits 91 and 92 is not specified in the present third embodiment, but for example, a series resonance circuit of an inductor and a capacitor arranged in series in each of the transmission lines 31 and 32 is conceivable. In addition, a parallel resonance circuit of an inductor and a capacitor arranged in parallel in each of the transmission lines 31 and 32 is conceivable. In the former case, the series resonance circuit is short-circuited at f1 so as not to affect characteristics of f1. In the latter case, the parallel resonance circuit is open at f1 so as not to affect characteristics of f1. The number of the matching circuits 91 is not limited to one, and a plurality of the matching circuits 91 may be arranged in the middle of the transmission line 31. Similarly, the number of the matching circuits 92 is not limited to one, and a plurality of the matching circuits 92 may be arranged in the middle of the transmission line 32. In addition, the matching circuits 91 and 92 are not necessarily required, and the matching circuits 91 and 92 do not have to be arranged in a case where a reflection amplitude is low at f2 even when the matching circuits 91 and 92 are not arranged.

As described above, in the decoupling circuit according to the third embodiment of the present invention, since a restriction condition on the antenna elements 1 and 2 is to reduce reflection of the antenna elements 1 and 2 with the reference impedance of formula (15) at f1, and to reduce mutual coupling at f2, the decoupling circuit can also be applied to an asymmetric two-element antenna, and the restriction on an impedance matrix of a two-element antenna can be reduced.

As described above, by the decoupling circuit being constituted by the antenna elements 1 and 2, the susceptances 13 and 21 to 24, the ground conductor 101, the transmission lines 33, 34, 35, and 36, the matching circuits 91 and 92, and the input and output terminals 51 and 52, it is possible to obtain a decoupling circuit having a small number of susceptances, having a small restriction on an impedance matrix of a two-element antenna, and being capable of reducing both mutual coupling and reflection at two frequencies.

Note that each of the susceptances 11 to 24 may be one inductor or capacitor, or may be implemented by combining a plurality of inductors and capacitors.

### REFERENCE SIGNS LIST

1, 2: antenna element, 11 to 24: susceptance, 31 to 37: transmission line, 51, 52: input and output terminal, 61: two-frequency shared phase shift circuit, 71 to 79: resonance circuit, 81: inductor, 82: capacitor, 91, 92: matching circuit, 101: ground conductor

1. A decoupling circuit comprising:
a first antenna element;
a second antenna element;
a ground conductor;
a first transmission line whose first end is connected to the first antenna element;
a second transmission line whose first end is connected to the second antenna element;
a first susceptance circuit whose first end is connected to a second end of the first transmission line;
a second susceptance circuit whose first end is connected to a second end of the second transmission line and whose second end is connected to a second end of the first susceptance circuit;
a third susceptance circuit whose first end is connected to the second end of the first susceptance circuit and whose second end is connected to the ground conductor;
a first input and output terminal connected to the first end of the first susceptance circuit; and
a second input and output terminal connected to the first end of the second susceptance circuit, wherein
the first susceptance circuit is a first parallel resonance circuit,
the second susceptance circuit is a second parallel resonance circuit.

2. A decoupling circuit comprising:
a first antenna element;
a second antenna element;
a ground conductor;
a two-frequency shared phase shift circuit whose first end is connected to the first antenna element;
a first susceptance circuit whose first end is connected to a second end of the two-frequency shared phase shift circuit;
a second susceptance circuit whose first end is connected to the second antenna element and whose second end is connected to a second end of the first susceptance circuit;
a third susceptance circuit whose first end is connected to the second end of the first susceptance circuit and whose second end is connected to the ground conductor;
a first input and output terminal connected to the first end of the first susceptance circuit; and
a second input and output terminal connected to the first end of the second susceptance circuit.

3. The decoupling circuit according to claim 2, wherein
the first susceptance circuit is a first resonance circuit,
the second susceptance circuit is a second resonance circuit, and
the third susceptance circuit is a third resonance circuit.

4. The decoupling circuit according to claim 3, wherein
the two-frequency shared phase shift circuit includes:
a fourth resonance circuit whose first end is connected to the first antenna element and whose second end is connected to the ground conductor;
a fifth resonance circuit whose first end is connected to a first end of the fourth resonance circuit; and
a sixth resonance circuit whose first end is connected to a second end of the fifth resonance circuit and the first end of the first susceptance circuit and whose second end is connected to the ground conductor.

5. The decoupling circuit according to claim 3, wherein
the two-frequency shared phase shift circuit includes:
a seventh resonance circuit whose first end is connected to the first antenna element;
an eighth resonance circuit whose first end is connected to the first end of the seventh resonance circuit and whose second end is connected to the ground conductor; and
a ninth resonance circuit whose first end is connected to the first end of the eighth resonance circuit and whose second end is connected to the first end of the first susceptance circuit.

6. A decoupling circuit comprising:
a first antenna element;
a second antenna element;
a ground conductor;
a first transmission line whose first end is connected to the first antenna element;
a second transmission line whose first end is connected to the second antenna element;
a first susceptance circuit whose first end is connected to a second end of the first transmission line;
a second susceptance circuit whose first end is connected to a second end of the second transmission line and whose second end is connected to a second end of the first susceptance circuit;
a third susceptance circuit whose first end is connected to the second end of the first susceptance circuit and whose second end is connected to the ground conductor;
a first input and output terminal connected to the first end of the first susceptance circuit; and
a second input and output terminal connected to the first end of the second susceptance circuit, wherein
the first transmission line is formed by connecting a third transmission line and a fourth transmission line in series,
the second transmission line is formed by connecting a fifth transmission line and a sixth transmission line in series,
the third susceptance circuit is a series resonance circuit, and
the decoupling circuit comprises:
a first matching circuit disposed between the third transmission line and the fourth transmission line; and
a second matching circuit disposed between the fifth transmission line and the sixth transmission line.

7. A decoupling circuit comprising:
a first antenna element;
a second antenna element;
a ground conductor;
a first transmission line whose first end is connected to the first antenna element;
a second transmission line whose first end is connected to the second antenna element;
a first susceptance circuit whose first end is connected to a second end of the first transmission line;
a second susceptance circuit whose first end is connected to a second end of the second transmission line and whose second end is connected to a second end of the first susceptance circuit;
a third susceptance circuit whose first end is connected to the second end of the first susceptance circuit and whose second end is connected to the ground conductor;
a first input and output terminal connected to the first end of the first susceptance circuit; and
a second input and output terminal connected to the first end of the second susceptance circuit, wherein
the first transmission line is formed by connecting a third transmission line and a fourth transmission line in series,
the second transmission line is formed by connecting a fifth transmission line and a sixth transmission line in series,
the third susceptance circuit is a seventh transmission line whose first end is connected to the second end of the first susceptance circuit and whose second end is open, and
the decoupling circuit comprises:
a first matching circuit disposed between the third transmission line and the fourth transmission line; and
a second matching circuit disposed between the fifth transmission line and the sixth transmission line.

8. The decoupling circuit according to claim 6, wherein
at a first frequency, each of a susceptance of the first susceptance circuit and a susceptance of the second susceptance circuit is an opposite number of a susceptance of the third susceptance circuit, and
at a second frequency, the third susceptance circuit is short-circuited.

9. The decoupling circuit according to claim 1, wherein
the first transmission line is formed by connecting a third transmission line and a fourth transmission line in series,
the second transmission line is formed by connecting a fifth transmission line and a sixth transmission line in series, and
the decoupling circuit comprises:
a first matching circuit disposed between the third transmission line and the fourth transmission line; and
a second matching circuit disposed between the fifth transmission line and the sixth transmission line.

10. The decoupling circuit according to claim 2, wherein
at a first frequency and a second frequency, each of a susceptance of the first susceptance circuit and a susceptance of the second susceptance circuit is an opposite number of a susceptance of the third susceptance circuit.

11. The decoupling circuit according to claim 1, wherein
at a first frequency, each of a susceptance of the first susceptance circuit and a susceptance of the second susceptance circuit is an opposite number of a susceptance of the third susceptance circuit, and
at a second frequency, the first susceptance circuit and the second susceptance circuit are open.
